(19) United States
(12) Patent Application Publication
(10) Pub. No.: US 2018/0121351 A1
(43) Pub. Date: May 3, 2018

(54) STORAGE SYSTEM, STORAGE MANAGEMENT APPARATUS, STORAGE DEVICE, HYBRID STORAGE APPARATUS, AND STORAGE MANAGEMENT METHOD

(71) Applicant: HUAWEI TECHNOLOGIES CO.,LTD., Shenzhen (CN)

(72) Inventors: Zigang Zhang, Beijing (CN); Jin Xiong, Beijing (CN); Dejun Jiang, Beijing (CN)

(73) Assignee: HUAWEI TECHNOLOGIES CO.,LTD., Shenzhen (CN)

(21) Appl. No.: 15/853,874

(22) Filed: Dec. 25, 2017

Related U.S. Application Data
(63) Continuation of application No. PCT/CN2016/081000, filed on May 4, 2016.

(30) Foreign Application Priority Data
Jun. 29, 2015 (CN) 201510369203.2

(51) Int. Cl. G06F 12/06; G11C 8/06; G06F 3/06

(52) U.S. Cl. CPC G06F 12/0646; G06F 3/064; G11C 8/06

(57) ABSTRACT

A storage system includes a storage device and a managing device. The managing device receives a data write request, determines a data category of a to-be-written data page, designates different logical blocks for to-be-written data pages of different data categories, and sends a data write instruction to the storage device, where the data write instruction carries to-be-written data pages corresponding to at least one designated logical block. The storage device is configured to receive the data write instruction, and write the to-be-written data page corresponding to the at least one designated logical block to a physical block corresponding to the at least one designated logical block, where to-be-written data pages written to each physical block are corresponding to a same logical block.

### CROSS-REFERENCE TO RELATED APPLICATIONS

This application is a continuation of International Application No. PCT/CN2016/081000, filed on May 4, 2016, which claims priority to Chinese Patent Application No. 201510369203.2, filed on Jun. 29, 2015, both of which are hereby incorporated by reference in their entireties.

### STATEMENT OF JOINT RESEARCH AGREEMENT

The subject matter and the claimed invention were made by or on the behalf of Tsinghua University, of Beijing, P. R. China and Huawei Technologies Co., Ltd., of Shenzhen, Guangdong Province, P. R. China, under a joint research agreement titled “High-throughput Server Research Project II”. The joint research agreement was in effect on or before the claimed invention was made, and that the claimed invention was made as a result of activities undertaken within the scope of the joint research agreement.

### TECHNICAL FIELD

The present application relates to the field of storage technologies, and in particular, to a storage system, a storage management apparatus, a storage device, a hybrid storage apparatus, and a storage management method.

### BACKGROUND

Solid state disks (SSDs) have advantages such as high performance, low delays, low power consumption, and strong environment adaptability. Their costs are increasingly reduced. Therefore, SSDs are currently in increased use, and are mainly used as cache for hard disk drives (HDDs).

Unlike a HDD, a SSD does not allow overwriting data at its original location, but requires erasure of original data before new data is written. In addition, the SSD is read and written in pages, but erasure is in physical blocks. Therefore, to update data in the SSD, updated data needs to be written to an unoccupied location, and the original data is invalidated. When the SSD is full, a physical block that has a relatively large quantity of invalid data is erased.

A physical block to be erased from the SSD may include a large quantity of valid pages, and therefore data in these valid pages needs to be copied to an idle (unoccupied) location before data in the physical block is erased. This process is called garbage collection. In the process of garbage collection, copying the data in these valid pages to an idle location adds extra data writing, that is, causes amplified write of the SSD. The writing amplification of the SSD reduces performance of the SSD, and shortens life of the SSD.

### SUMMARY

Embodiments of the present application provide an SSD storage management apparatus and method, to reduce the writing amplification problem occurring in an SSD storage in a data erasure process.

A first aspect of the embodiments of the present application provides a storage system, including a storage device and a managing device, where

the storage device includes multiple physical blocks;

the managing device is configured to: receive a data write request, determine a data category of a to-be-written data page, designate different logical blocks for to-be-written data pages of different data categories, and send a data write instruction to the storage device, where each designated logical block is corresponding to to-be-written data pages of a same data category, and the data write instruction carries to-be-written data pages corresponding to at least one designated logical block; and

the storage device is configured to receive the data write instruction, and write, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

With reference to the first aspect, in a first possible implementation manner, a correspondence between physical blocks and logical blocks is further preconfigured in the storage device, where each physical block is corresponding to one logical block, and each logical block is corresponding to at least one physical block;

the managing device is further configured to add information about the at least one logical block into the data write instruction; and

after receiving the data write instruction, the storage device is specifically configured to: query the correspondence between physical blocks and logical blocks according to the information that is about the at least one logical block and that is in the data write instruction, determine the physical block corresponding to the at least one logical block, and write the to-be-written data pages corresponding to the at least one logical block to the physical block corresponding to the at least one logical block.

With reference to the first aspect, in a second possible implementation manner, the storage system further includes at least one cache, and a capacity of each cache is less than or equal to a capacity of each logical block;

after receiving the data write request, the managing device is specifically configured to: write the to-be-written data pages of different data categories to different caches, designate at least one logical block for data pages that are of a same data category and that are in each fully written cache, and send the data write instruction to the storage device, where to-be-written data pages written to each cache are of a same data category, and the data write instruction carries information about the at least one logical block and the to-be-written data pages corresponding to the at least one logical block; and

after receiving the data write instruction, the storage device is specifically configured to: according to the data write instruction, allocate a physical block to the at least one logical block, and write the data pages corresponding to the at least one logical block to the allocated physical block, where a physical block allocated to each logical block of the at least one logical block is an idle physical block in the storage device, and the idle physical block is marked as non-idle after being allocated; a total capacity of the physical block allocated to each logical block of the at least one logical block is greater than or equal to a capacity of each logical block in the at least one logical block.

With reference to the second implementation manner of the first aspect, in a third possible implementation manner, the storage device is further configured to record a correspondence between physical blocks and logical blocks according to the information that is about the at least one logical block and that is in the data write instruction and information about the physical block allocated to the at least one logical block.

With reference to the first possible implementation manner or the third possible implementation manner of the first aspect, in a fourth possible implementation manner, the managing device is further configured to record, in the at least one logical block, a logical block address of each to-be-written data page corresponding to the at least one logical block, and record a data category of the data pages corresponding to the at least one logical block.

With reference to the fourth possible implementation manner of the first aspect, in a fifth possible implementation manner, the managing device is further configured to determine a to-be-erased logical block according to data pages corresponding to each logical block, and send an erase instruction to the storage device, where the erase instruction carries information about the to-be-erased logical block; and

the storage device is further configured to receive the erase instruction, determine a to-be-erased physical block according to the information that is about the to-be-erased logical block and that is in the erase instruction and the correspondence between physical blocks and logical blocks, and erase the to-be-erased physical block.

With reference to the fifth possible implementation manner of the first aspect, in a sixth possible implementation manner, the data categories are cold data and hot data that are determined according to data access frequency; the managing device is further configured to: when it is determined that a stored data page needs to be updated, invalidate a logical block address that is of the stored data page and that is recorded into a logical block corresponding to the stored data page; and

that the managing device is configured to determine a to-be-erased logical block according to data pages corresponding to each logical block specifically includes: selecting, as the to-be-erased logical block, a logical block whose data category is hot data or a logical block that has a large quantity of invalid logical block addresses.

With reference to the fifth possible implementation manner of the first aspect, in a seventh possible implementation manner, the data categories are cold data and hot data that are determined according to data access frequency; that the managing device is configured to determine a to-be-erased logical block according to data pages corresponding to each logical block specifically includes: selecting, as the to-be-erased logical block, a logical block whose data category is cold data; and

the managing device is further configured to add a garbage collection forbidding indication into the erase instruction.

With reference to the fifth, the sixth, or the seventh possible implementation manner of the first aspect, in an eighth possible implementation manner, before the managing device sends the erase instruction to the storage device, the managing device is further configured to determine a to-be-migrated data page in the to-be-erased logical block according to a preset migration policy, and send a data migration instruction to the storage device, where the data migration instruction carries information about the to-be-migrated data page; and

the storage device is further configured to migrate the to-be-migrated data page in the storage device according to the data migration instruction.

With reference to the eighth possible implementation manner of the first aspect, in a ninth possible implementation manner, that the managing device is further configured to determine a to-be-migrated data page in the to-be-erased logical block according to a preset migration policy specifically includes: determining a data page in the to-be-erased logical block as the to-be-migrated data page, where a current data category of the data page is hot data, and a logical block address of the data page is valid.

According to a second aspect, a storage management apparatus is provided and is applied to a storage system that includes a storage device. The storage device includes multiple physical blocks, and the storage management apparatus includes:

a classification module, configured to receive a data write request and determine a data category of a to-be-written data page;

a logical block management module, configured to designate different logical blocks for to-be-written data pages of different data categories according to a classification result of the classification module, where each designated logical block is corresponding to to-be-written data pages of a same data category; and

a write instruction module, configured to send a data write instruction to the storage device according to the logical blocks designated by the logical block management module for the to-be-written data pages, where the data write instruction carries to-be-written data pages corresponding to at least one logical block, and the data write instruction is used to instruct the storage device to write, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

With reference to the second aspect, in a first possible implementation manner, the data write instruction further carries information about the at least one logical block; and

the data write instruction is specifically used to instruct the storage device to: query, according to the information that is about the at least one logical block and that is in the data write instruction, a correspondence between physical blocks and logical blocks that is preset in the storage device, determine the physical block corresponding to the at least one logical block, and write the to-be-written data pages corresponding to the at least one logical block to the physical block corresponding to the at least one logical block.

With reference to the second aspect, in a second possible implementation manner, the storage management apparatus further includes:

a cache write module, configured to write the to-be-written data pages of different data categories to different caches according to the classification result of the classification module, where the to-be-written data pages of a same data category are written to a same cache, and a capacity of each cache is less than or equal to a capacity of each logical block; where

the logical block management module is configured to designate one logical block for data pages that are of a same data category and that are in each fully written cache; and

the write instruction module is specifically configured to send the data write instruction to the storage device according to the logical blocks designated by the logical block management module for the to-be-written data pages, where the data write instruction carries information about the at least one logical block and the data pages corresponding to the at least one logical block, and the data write instruction is specifically used to instruct the storage device to allocate a physical block to the at least one logical block, and to write the data pages corresponding to the at least one logical block to the allocated physical block, where a physical block allocated to each logical block of the at least one logical block is an idle physical block in the storage device, and the idle physical block is marked as non-idle after being allocated; a total capacity of the physical block allocated to each logical block of the at least one logical block is greater than or equal to a capacity of each logical block in the at least one logical block.

With reference to the first implementation manner or the second implementation manner of the second aspect, in a third possible implementation manner, the logical block management module is further configured to record, into the at least one logical block, a logical block address of each to-be-written data page corresponding to the at least one logical block, and record a data category of the data pages corresponding to the at least one logical block.

With reference to the third possible implementation manner of the second aspect, in a fourth possible implementation manner, the storage management apparatus further includes: an erase instruction module, configured to determine a to-be-erased logical block according to data pages corresponding to each logical block, and send an erase instruction to the storage device, where the erase instruction carries information about the to-be-erased logical block, and the erase instruction is used to instruct the storage device to determine a to-be-erased physical block according to the information that is about the to-be-erased logical block and that is in the erase instruction and the correspondence between physical blocks and logical blocks that is set in the storage device, and to erase the to-be-erased physical block.

With reference to the fourth possible implementation manner of the second aspect, in a fifth possible implementation manner, the data categories are cold data and hot data that are determined according to data access frequency; the logical block management module is further configured to: when it is determined that a stored data page needs to be updated, invalidate a logical block address that is of the stored data page and that is recorded into a logical block corresponding to the stored data page; and

that an erase instruction module is configured to determine a to-be-erased logical block specifically includes: selecting, as the to-be-erased logical block, a logical block whose data category is hot data or a logical block that has a large quantity of invalid logical block addresses.

With reference to the fourth possible implementation manner of the second aspect, in a sixth possible implementation manner, the data categories are cold data and hot data that are determined according to data access frequency; that the erase instruction module is configured to determine a to-be-erased logical block specifically includes: selecting, as the to-be-erased logical block, a logical block whose data category is cold data; and

the erase instruction module is further configured to add a garbage collection forbidding indication into the erase instruction.

With reference to the fourth, the fifth, or the sixth possible implementation manner of the second aspect, in a seventh possible implementation manner, the storage management apparatus further includes a migration instruction module; before the erase instruction module sends the erase instruction to the storage device, the migration instruction module is configured to determine a to-be-migrated data page in the to-be-erased logical block according to a preset migration policy, and send a data migration instruction to the storage device, where the data migration instruction carries information about the to-be-migrated data page, and the data migration instruction is used to instruct the storage device to migrate the to-be-migrated data page in the storage device.

With reference to the seventh possible implementation manner of the second aspect, in an eighth possible implementation manner, that the migration instruction module determines a to-be-migrated data page in the to-be-erased logical block according to a preset migration policy specifically includes: determining a data page in the to-be-erased logical block as the to-be-migrated data page, where a current data category of the data page is hot data, and a logical block address of the data page is valid.

According to a third aspect, a storage device is provided, including:

a receiving module, configured to receive a data write instruction, where the data write instruction carries to-be-written data pages corresponding to at least one logical block, the data write instruction is sent by a managing device after the managing device determines a data category of the to-be-written data pages and designates different logical blocks for to-be-written data pages of different data categories, where each designated logical block is corresponding to to-be-written data pages of a same data category; and

a writing module, configured to write, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

With reference to the third aspect, in a first possible implementation manner, the storage device includes a preset correspondence between physical blocks and logical blocks, where each physical block is corresponding to one logical block, and each logical block is corresponding to at least one physical block;

the data write instruction received by the receiving module further carries information about the at least one logical block; and

after the receiving module receives the data write instruction, the writing module is specifically configured to: query, according to the information that is about the at least one logical block and that is in the data write instruction, a correspondence between physical blocks and logical blocks that is preconfigured by the configuration module, determine the physical block corresponding to the at least one logical block, and write the to-be-written data pages corresponding to the at least one logical block to the physical block corresponding to the at least one logical block.

With reference to the third aspect, in a second possible implementation manner, the data write instruction is sent by the managing device after the managing device writes the to-be-written data pages of different data categories into different caches and designates at least one logical block for data pages that are of a same data category and that are in each fully written cache, where the to-be-written data pages written to each cache are of a same data category; and

after the receiving module receives the data write instruction, the writing module is specifically configured to: according to the data write instruction, allocate a physical block to the at least one logical block and write the data pages corresponding to the at least one logical block to the allocated physical block, where a physical block allocated to each logical block of the at least one logical block is an idle physical block in the storage device, and the idle physical block is marked as non-idle after being allocated; a total capacity of the physical block allocated to each logical block of the at least one logical block is greater than or equal to a capacity of each logical block in the at least one logical block.

With reference to the second possible implementation manner of the third aspect, in a third possible implementation manner, the writing module is further configured to record a correspondence between physical blocks and logical blocks according to the information that is about the at least one logical block and that is in the data write instruction and information about the physical block allocated to the at least one logical block.

With reference to the third possible implementation manner of the third aspect, in a fourth possible implementation manner, the receiving module is further configured to receive an erase instruction sent by the managing device, where the erase instruction is sent by the managing device after the managing device determines a to-be-erased logical block, and the erase instruction carries information about the to-be-erased logical block; and

the storage device further includes: an erasing module, configured to determine a to-be-erased physical block according to the information that is about the to-be-erased logical block and that is in the erase instruction and the correspondence between physical blocks and logical blocks, and erase the to-be-erased physical block.

With reference to the fourth possible implementation manner of the third aspect, in a fifth possible implementation manner, the receiving module is further configured to receive a data migration instruction sent by the managing device, where the data migration instruction is sent by the managing device after the managing device determines a to-be-migrated data page in the to-be-erased logical block according to a preset migration policy, and the data migration instruction carries information about the to-be-migrated data page; and

the storage device further includes a migration module, configured to migrate the to-be-migrated data page in the storage device according to the data migration instruction.

According to a fourth aspect, a hybrid storage apparatus is provided and includes: a hard disk drive, the managing device in any one of the implementation manners of the second aspect, and the storage device described in any one of the implementation manners of the third aspect, where the storage device is used as a cache of the magnetic disk storage device.

According to a fifth aspect, a storage management method is provided and is applied to a storage system that includes a storage device. The storage device includes multiple physical blocks, and the method includes:

receiving a data write request and determining a data category of a to-be-written data page;

designating different logical blocks for to-be-written data pages of different data categories, where each designated logical block is corresponding to to-be-written data pages of a same data category; and

sending a data write instruction to the storage device according to the logical blocks designated for the to-be-written data pages, where the data write instruction carries to-be-written data pages corresponding to at least one logical block, and the data write instruction is used to instruct the storage device to write, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

With reference to the fifth aspect, in a first possible implementation manner, the data write instruction further carries information about the at least one logical block; and

the data write instruction further instructs the storage device to: query, according to the information that is about the at least one logical block and that is in the data write instruction, a correspondence between physical blocks and logical blocks that is preset in the storage device, determine the physical block corresponding to the at least one logical block, and write the to-be-written data pages corresponding to the at least one logical block to the physical block corresponding to the at least one logical block.

With reference to the fifth aspect, in a second possible implementation manner, the method further includes:

writing the to-be-written data pages of different data categories into different caches, where the to-be-written data pages of a same data category are written to a same cache, and a capacity of each cache is less than or equal to a capacity of each logical block;

designating one logical block for data pages that are of a same data category and that are in each fully written cache; and

sending the data write instruction to the storage device according to the logical blocks designated for the to-be-written data pages, where the data write instruction carries information about the at least one logical block and the data pages corresponding to the at least one logical block; where

the data write instruction is specifically used to instruct the storage device to allocate a physical block to the at least one logical block, and to write the data pages corresponding to the at least one logical block to the allocated physical block, where a physical block allocated to each logical block of the at least one logical block is an idle physical block in the storage device, and the idle physical block is marked as non-idle after being allocated; a total capacity of the physical block allocated to each logical block of the at least one logical block is greater than or equal to a capacity of each logical block in the at least one logical block.

With reference to the first or the second possible implementation manner of the fifth aspect, in a third possible implementation manner, after the designating different logical blocks for to-be-written data pages of different data categories, the storage management method further includes: recording, into the at least one logical block, a logical block address of each to-be-written data page corresponding to the at least one logical block, and recording a data category of the data pages corresponding to the at least one logical block.

With reference to the third possible implementation manner of the fifth aspect, in a fourth possible implementation manner, the method further includes: determining a to-be-erased logical block according to data pages corresponding to each logical block, and sending an erase instruction to the storage device, where the erase instruction carries information about the to-be-erased logical block, and the erase instruction is used to instruct the storage device to determine a to-be-erased physical block according to the information that is about the to-be-erased logical block and that is in the erase instruction and the correspondence between physical blocks and logical blocks that is set in the storage device, and to erase the to-be-erased physical block.

With reference to the fourth possible implementation manner of the fifth aspect, in a fifth possible implementation manner, the data categories are cold data and hot data that are determined according to data access frequency; the method further includes: when it is determined that a stored data page needs to be updated, invalidating a logical block address that is of the stored data page and that is recorded into a logical block corresponding to the stored data page; and

the determining a to-be-erased logical block specifically includes: selecting, as the to-be-erased logical block, a logical block whose data category is hot data or a logical block that has a large quantity of invalid logical block addresses.

With reference to the fourth possible implementation manner of the fifth aspect, in a sixth possible implementation manner, the data categories are cold data and hot data that are determined according to data access frequency; and

the determining a to-be-erased logical block specifically includes: selecting, as the to-be-erased logical block, a logical block whose data category is cold data; and

adding a garbage collection forbidding indication into the erase instruction.

With reference to the fourth, the fifth, or the sixth possible implementation manner of the fifth aspect, in a seventh possible implementation manner, before the sending the erase instruction to the storage device, the storage management method further includes: determining a to-be-migrated data page in the to-be-erased logical block according to a preset migration policy, and sending a data migration instruction to the storage device, where the data migration instruction carries information about the to-be-migrated data page, and the data migration instruction is used to instruct the storage device to migrate the to-be-migrated data page in the storage device.

With reference to the seventh possible implementation manner of the fifth aspect, in an eighth possible implementation manner, the determining a to-be-migrated data page in the to-be-erased logical block according to a preset migration policy specifically includes: determining a data page in the to-be-erased logical block as the to-be-migrated data page, where a current data category of the data page is hot data, and a logical block address of the data page is valid.

According to a sixth aspect, a storage management method is provided and is applied to a storage device, including:

receiving a data write instruction, where the data write instruction carries to-be-written data pages corresponding to at least one logical block, the data write instruction is sent by a managing device after the managing device determines a data category of the to-be-written data pages and designates different logical blocks for to-be-written data pages of different data categories, where each designated logical block is corresponding to to-be-written data pages of a same data category; and

writing, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

With reference to the sixth aspect, in a first possible implementation manner, the storage device includes a preset correspondence between physical blocks and logical blocks, where each physical block is corresponding to one logical block, and each logical block is corresponding to at least one physical block;

the data write instruction further carries information about the at least one logical block; and

after the data write instruction is received, the writing, according to the data write instruction, the to-be-written data pages corresponding to the at least one logical block to a physical block corresponding to the at least one logical block specifically includes: querying the correspondence between physical blocks and logical blocks according to the information that is about the at least one logical block and that is in the data write instruction, determining the physical block corresponding to the at least one logical block, and writing the to-be-written data pages corresponding to the at least one logical block to the physical block corresponding to the at least one logical block.

With reference to the sixth aspect, in a second possible implementation manner, the data write instruction is sent by the managing device after the managing device writes the to-be-written data pages of different data categories into different caches and designates at least one logical block for data pages that are of a same data category and that are in each fully written cache, where the to-be-written data pages written to each cache are of a same data category; and

after the data write instruction is received, the writing, according to the data write instruction, the to-be-written data pages corresponding to the at least one logical block to a physical block corresponding to the at least one logical block specifically includes: according to the data write instruction, allocating a physical block to the at least one logical block and writing the data pages corresponding to the at least one logical block to the allocated physical block, where a physical block allocated to each logical block of the at least one logical block is an idle physical block in the storage device, and the idle physical block is marked as non-idle after being allocated; a total capacity of the physical block allocated to each logical block of the at least one logical block is greater than or equal to a capacity of each logical block in the at least one logical block.

With reference to the second possible implementation manner of the sixth aspect, in a third possible implementation manner, the storage management method further includes: recording a correspondence between physical blocks and logical blocks according to the information that is about the at least one logical block and that is in the data write instruction and information about the physical block allocated to the at least one logical block.

With reference to the third possible implementation manner of the sixth aspect, in a fourth possible implementation manner, the storage management method further includes:

receiving an erase instruction sent by the managing device, where the erase instruction is sent by the managing device after the managing device determines a to-be-erased logical block, and the erase instruction carries information about the to-be-erased logical block; and

determining a to-be-erased physical block according to the information that is about the to-be-erased logical block and that is in the erase instruction and the correspondence between physical blocks and logical blocks, and erasing the to-be-erased physical block.

With reference to the fourth possible implementation manner of the sixth aspect, in a fifth possible implementation manner, the method further includes:

receiving a data migration instruction sent by the managing device, where the data migration instruction is sent by the managing device after the managing device determines a to-be-migrated data page in the to-be-erased logical block according to a preset migration policy, and the data migration instruction carries information about the to-be-migrated data page; and

migrating the to-be-migrated data page in the storage device according to the data migration instruction.

According to a seventh aspect, a storage managing device is provided and includes: a processor, a storage device, a bus, and a communications interface, where the storage device is configured to store a computer executable instruction, the processor is connected to the storage device by using the bus, and when the computing device runs, the processor executes the computer executable instruction stored in the storage device, so that the storage managing device executes the following method:

receiving a data write request and determining a data category of a to-be-written data page;

designating different logical blocks for to-be-written data pages of different data categories, where each designated logical block is corresponding to to-be-written data pages of a same data category; and

sending a data write instruction to the storage device according to the logical blocks designated for the to-be-written data pages, where the data write instruction carries to-be-written data pages corresponding to at least one logical block, and the data write instruction is used to instruct the storage device to write, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

According to an eighth aspect, a storage managing device is provided and includes: a processor, a storage device, a bus, and a communications interface, where the storage device is configured to store a computer executable instruction, the processor is connected to the storage device by using the bus, and when the computing device runs, the processor executes the computer executable instruction stored in the storage device, so that the storage managing device executes the following method:

receiving a data write instruction, where the data write instruction carries to-be-written data pages corresponding to at least one logical block, the data write instruction is sent by a managing device after the managing device determines a data category of the to-be-written data pages and designates different logical blocks for to-be-written data pages of different data categories, where each designated logical block is corresponding to to-be-written data pages of a same data category; and

writing, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

According to a ninth aspect, a computer readable medium is provided and includes a computer executable instruction, where when a processor of a computer executes the computer executable instruction, the computer executes the following method:

receiving a data write request and determining a data category of a to-be-written data page;

designating different logical blocks for to-be-written data pages of different data categories, where each designated logical block is corresponding to to-be-written data pages of a same data category; and

sending a data write instruction to the storage device according to the logical blocks designated for the to-be-written data pages, where the data write instruction carries to-be-written data pages corresponding to at least one logical block, and the data write instruction is used to instruct the storage device to write, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

According to a tenth aspect, a computer readable medium is provided and includes a computer executable instruction, where when a processor of a computer executes the computer executable instruction, the computer executes the following method:

receiving a data write instruction, where the data write instruction carries to-be-written data pages corresponding to at least one logical block, the data write instruction is sent by a managing device after the managing device determines a data category of the to-be-written data pages and designates different logical blocks for to-be-written data pages of different data categories, where each designated logical block is corresponding to to-be-written data pages of a same data category; and

writing, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

According to an eleventh aspect, a storage system is provided and includes a storage device and a managing device; where

the storage device includes multiple physical blocks;

the managing device is configured to: receive a data write request, determine a data category of a to-be-written data page, and send a data write instruction to the storage device, where the data write instruction carries the to-be-written data page and the data category of the to-be-written data page; and

the storage device is configured to receive the data write instruction, and write, according to the data write instruction, the to-be-written data page to a physical block corresponding to the data category of the to-be-written data page, where to-be-written data pages with a same data category are written to at least one physical block, and each physical block is written to-be-written data pages with a same data category.

In the present application, to-be-written data pages are classified so that each physical block in an SSD stores data pages of a same data category. Because the data pages of a same data category are updated at a basically consistent pace, quantities of valid data pages are in normal distribution in the physical blocks in accordance with the data categories of data pages in the physical blocks. For example, a physical block in which hot data that is frequently accessed is located has a relatively large quantity of invalid data pages, and a physical block in which cold data that is infrequently accessed is located has a relatively small quantity of invalid data pages. Such distribution of validity of data pages is different from that in the case of random writing in the prior art. A quantity of valid data pages in a to-be-erased physical block selected by the SSD according to a quantity of invalid data pages during garbage collection is necessarily less than a quantity of valid data pages in a to-be-erased physical block selected in the prior art. Therefore, in the method provided in the embodiments of the present application, write amplification resulting when a physical block is erased is reduced.

### BRIEF DESCRIPTION OF DRAWINGS

The following briefly describes the accompanying drawings used in describing the embodiments or the prior art.

FIG. 1 is an architecture diagram of a system in which an SSD is used as a cache of an HDD;

FIG. 2 is a schematic diagram of changing data address during data updating of an SSD;

FIG. 3 is an simplified block diagram of a storage system according to an embodiment of the present application;

FIG. 4 is a schematic diagram of a correspondence between data categories, logical blocks, and physical blocks according to an embodiment of the present application;

FIG. 5 is a schematic diagram of a process of writing a to-be-written data page in a data write request to an SSD according to an embodiment of the present application;

FIG. 6 is a schematic diagram of changing a logical block address in a logical block during updating of stored data according to an embodiment of the present application;

FIG. 7 is a schematic diagram of migrating data in a to-be-erased physical block before erasing the physical block according to an embodiment of the present application;

FIG. 8 is an architecture diagram of a second storage system according to an embodiment of the present application;

FIG. 9 is a functional block diagram of a first storage management apparatus according to an embodiment of the present application;

FIG. 10 is a functional block diagram of a second storage management apparatus according to an embodiment of the present application;

FIG. 11 is a simplified structural diagram of an SSD according to an embodiment of the present application;

FIG. 12 is a structural diagram of a hybrid storage apparatus according to an embodiment of the present application;

FIG. 13 is a flowchart of a method for writing data to an SSD by a managing device according to an embodiment of the present application;

FIG. 14 is a flowchart of a first specific implementation method for writing data to an SSD by a managing device according to an embodiment of the present application;

FIG. 15 is a flowchart of a second specific implementation method for writing data to an SSD by a managing device according to an embodiment of the present application;

FIG. 16 is a flowchart of a method for controlling, by a managing device, an SSD to perform data erasure according to an embodiment of the present application; and

FIG. 17 is a schematic block diagram of a storage managing device according to an embodiment of the present application.

### DESCRIPTION OF EMBODIMENTS

A storage device in the embodiments of the present application includes multiple physical blocks, and new data can be written only when original data is erased. Data is written in pages, but erased in physical blocks. An SSD is a representative of such memories. The following embodiments are described by using an SSD as an example.

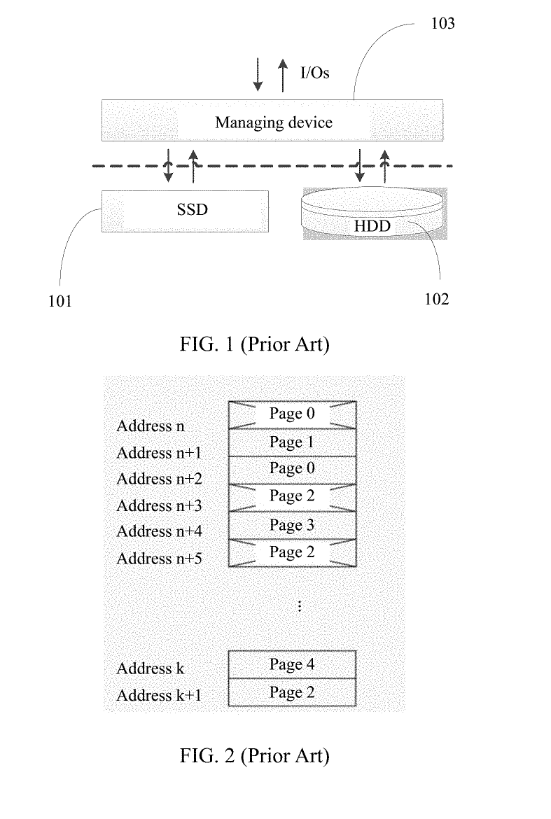

FIG. 1 is an architecture diagram of a system in which an SSD is used as a cache of an HDD in the prior art. Generally, frequently accessed data is stored in an SSD 101, and a managing device 103 performs centralized management on the SSD 101 and an HDD 102. The managing device 103 records, by using a mapping table, which data of the HDD 102 is cached in the SSD 101. When a request arrives, the managing device 103 searches the mapping table to determine whether requested data is stored in the SSD 101. If the data is stored in the SSD 101, the data is read from the SSD 101; or if the data is not in the SSD 101, the data is read from the HDD 102. If the SSD 101 is fully written with data, data erasure is performed, so that infrequently used data is replaced.

For the architecture shown in FIG. 1, when the SSD 101 and the HDD 102 are used as a hybrid drive, the managing device 103 may be a controller of the hybrid drive; when the SSD and the HDD are separately connected to a computer as independent devices, the managing device 103 may be loaded in an operating system of the computer or may be loaded onto the computer as an independent module. The foregoing SSD 101 in FIG. 1 is used as a cache of the HDD, and in another application scenario, the SSD 101 may be used as an independent storage device. The present application may be applied to the architecture shown in FIG. 1, or may be applied to another application scenario of the SSD 101.

The SSD is generally a NAND (not and) flash drive and may include multiple (for example, 1024) physical blocks, and each physical block includes multiple (for example, 64) physical pages. A physical page is a basic unit of data reading and data writing, and a physical block is a basic unit for the SSD to perform data erasure.

The SSD includes a flash translation layer (FTL), and the FTL may be used to record a correspondence between logical block addresses (LBA) of data and physical block addresses (PBA) in the SSD, and execute a data read operation or a data write operation according to the correspondence between logical block addresses and physical block addresses.

In addition, when data in the SSD needs to be updated, the FTL may further write, to an idle physical page of the SSD, “new data” resulting after updating, update the correspondence between LBAs of data and PBAs in the SSD, and mark a physical page that includes “old data” as an invalid page. As shown in FIG. 2, if a data updating request is to update data in Page 0, the FTL writes updated data in Page 0 to a physical page whose physical block address is n+2, and marks, as invalid, a physical page in which “old data” in Page 0 is located and whose physical block address is n.

After the SSD is fully written, a physical block needs to be replaced, and the FTL selects a physical block that has a relatively large quantity of invalid pages to erase, so as to free space for storage of new data. However, because a physical block erased by the SSD may include a large quantity of valid data pages, data pages in these valid pages need to be migrated to another idle location before data in the physical block that needs to be erased is erased. This process is garbage collection. Because in the process of garbage collection, the data in the valid pages needs to be migrated to another idle location, migration of the valid pages brings about extra writing, and a quantity of times of data writing inside the SSD is increased, that is, write amplification is caused.

A technical solution provided in the embodiments of the present application is intended to reduce write amplification resulting when a physical block is erased. The technical solution provided in the embodiments of the present application is as follows: A managing device classifies, into multiple data categories (for example, hot data, warm data, and cold data) according to an access status, data that needs to be written to an SSD, and then modifies the SSD, so that when storing data, the SSD stores data of a same data category in a same physical block. Because data pages of a same data category are updated at a basically consistent pace, quantities of valid data pages are in normal distribution in the physical blocks in accordance with the data categories of data pages in the physical blocks. For example, a physical block in which hot data that is frequently accessed is located has a relatively large quantity of invalid data pages, and a physical block in which cold data that is infrequently accessed is located has a relatively small quantity of invalid data pages. Such distribution of validity of data pages is different from that in the case of random writing in the prior art. A quantity of valid data pages in a to-be-erased physical block selected by the SSD according to a quantity of invalid data pages during garbage collection is necessarily less than a quantity of valid data pages in a to-be-erased physical block selected in the prior art. Therefore, in the method provided in the embodiments of the present application, write amplification resulting when a physical block is erased is reduced.

The following describes the technical solution in detail by using different embodiments of the present application.

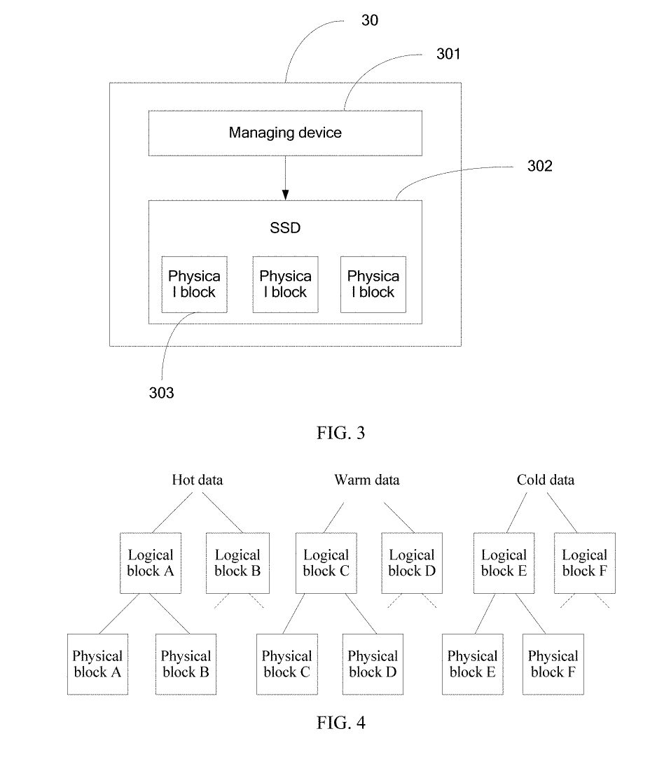

FIG. 3 is an architecture diagram of a first storage system 30 according to an embodiment of the present application. The first storage system 30 includes a managing device 301 and an SSD 302. The SSD 302 includes multiple physical blocks 303. The managing device 301 receives a data write request, determines a data category of a to-be-written data page, designates different logical blocks for to-be-written data pages of different data categories, and sends a data write instruction to the SSD 302. Each logical block is corresponding to to-be-written data pages of a same data category, and the data write instruction carries to-be-written data pages corresponding to at least one logical block.

The SSD 302 is configured to receive the data write instruction, and write, according to the data write instruction, the to-be-written data pages corresponding to the at least one logical block to a physical block 303 corresponding to the at least one logical block. To-be-written data pages corresponding to a same logical block are written to at least one physical block 303, and to-be-written data pages written to each physical block 303 are corresponding to a same logical block.

The data write request received by the managing device 301 is used to write data to the SSD 302, and the data written to the SSD 302 may be data written to the storage system 30 for the first time, or may be data resulting from updating data already stored in the SSD 302, or may be data transferred from the hard disk drive (not shown in the figure) to the SSD 302.

Because the SSD 302 writes data in pages, after receiving the data write request, the managing device 301 further classifies to-be-written data included in the data write request into multiple data pages, and then separately determines a data category of each to-be-written data page.

The managing device 301 classifies the data pages into multiple data categories. In this embodiment, the data category is a data access category. The managing device classifies the data pages into multiple data access categories according to an access characteristic of the data. The access characteristic may be a quantity of access times of the data page, a reuse distance of the data page, an access frequency of the data page, or a comprehensive characteristic of a quantity of access times and a reuse distance that are of the data page. The quantity of access times is a quantity of times that the to-be-written data page is accessed. The reuse distance is a quantity of data pages separating two accesses to the data page, that is, if a data page is accessed, and an operating system accesses the data page again after accessing seven data pages, a reuse distance of the data page is 7. The access characteristic may further be a quantity of times that the data page is read or written, or the like. The access characteristic may be specifically set according to an actual situation.

In this embodiment, the data access categories include a combination of any two categories or all categories of cold data, hot data, or warm data. For example, as shown in Table 1, when the access characteristic is the quantity of access times, it may be defined that a data page whose quantity of access times (N) is greater than or equal to 15 is hot data, a data page whose quantity of access times is less than 15 and greater than or equal to 5 is warm data, and a data page whose quantity of access times is less than 5 is cold data.

TABLE 1
Category Defining Table

| Access characteristic | Category |
|---|---|
| N ≥ 15 | Hot data |
| 5 < N ≤ 15 | Warm data |
| N < 5 | Cold data |

The foregoing classification and definition of the data categories are only an example for description, and do not impose any limitation in actual application. For example, classification may be performed according to different sources of data; for example, data from different applications is classified according to different applications.

For the data written to the first storage system for the first time, the managing device 301 may predefine a data category of the data. For example, a data category of the data written to the first storage system 301 for the first time may be considered as hot data by default.

In this embodiment, a correspondence between data categories and logical blocks and a correspondence between logical blocks and physical blocks in an SSD are shown in FIG. 4, that is, one data category may be corresponding to at least one logical block, and one logical block can be corresponding to only one data category; similarly, one logical block may be corresponding to at least one physical block 303 in the SSD 302, and one physical block 303 in the SSD 302 can be corresponding to only one logical block. In this way, it may be ensured that data pages recorded into each logical block are of a same data category, and each physical block stores data in only one logical block, that is, stores data pages of a same data category.

The correspondence between data categories and logical blocks that is shown in FIG. 4 may be pre-established by the managing device 301, that is, the managing device 301 divides logical space of the SSD 302 into multiple logical blocks in advance, and designates at least one logical block for each data category, for example, designates a logical block A and a logical block B for hot data, designates a logical block C and a logical block D for warm data, and designates a logical block E and a logical block F for cold data. In this case, after determining the data category of the to-be-written data page, the managing device 301 may designate a logical block corresponding to the determined data category of the to-be-written data page for the to-be-written data page.

Alternatively, the correspondence between data categories and logical blocks that is shown in FIG. 4 is not pre-established by the managing device 301. Instead, after the managing device 301 determines a data category of each to-be-written data page, if the determined data category of the to-be-written data page has no corresponding logical block, the managing device 301 randomly designates one logical block for the to-be-written data page, and then establishes a correspondence between the determined data category of the to-be-written data page and the designated logical block; or if the determined data category has a corresponding logical block, the managing device 301 designates the logical block corresponding to the determined data category for the to-be-written data page. In this embodiment, after designating a logical block for the to-be-written data page, the managing device 301 is further configured to record, into the logical block designated for the to-be-written data page, a logical block address of each to-be-written data page corresponding to each logical block.

A correspondence between physical blocks 303 and logical blocks is preconfigured in the SSD 302. Each physical block 303 is corresponding to one logical block, and each logical block is corresponding to at least one physical block 303. The correspondence between physical blocks 303 and logical blocks is shown in FIG. 4. In this way, after receiving the data write instruction, the SSD 302 may query the correspondence between physical blocks and logical blocks according to information that is about the at least one logical block and that is in the data write instruction, determine the physical block 303 corresponding to the at least one logical block, and write the to-be-written data pages corresponding to the at least one logical block to the physical block 303 corresponding to the at least one logical block. Data stored in a same physical block 303 may be of a same data category in the foregoing manner.

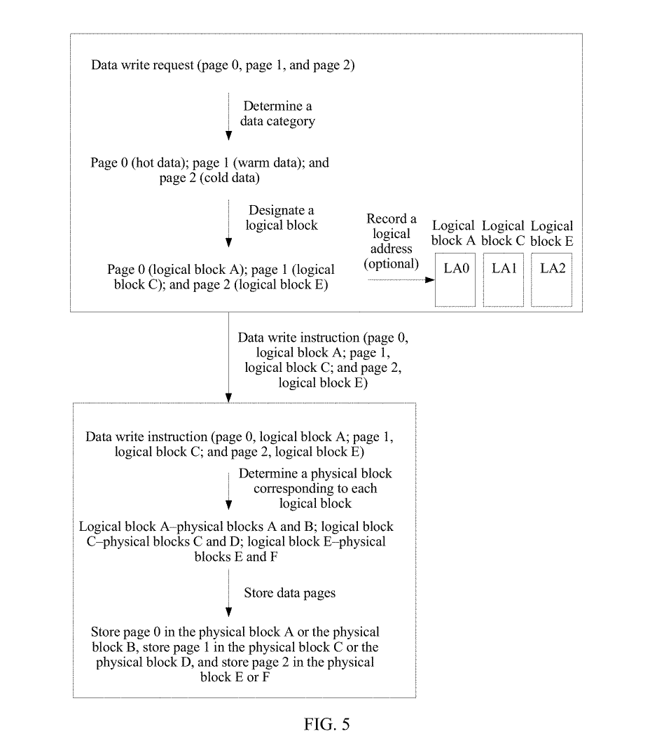

To describe more clearly a process of writing the to-be-written data pages in the data write request to the SSD, an example shown in FIG. 5 is used for detailed description. In the example shown in FIG. 5, the data write request received by the managing device 301 includes to-be-written data pages Page 0, Page 1, and Page 2. The managing device 301 determines a data category of each of the Page 0, the Page 1, and the Page 2 according to access characteristics of the Page 0, the Page 1, and the Page 2, that is, the Page 0 is hot data, the Page 1 is warm data, and the Page 2 is cold data. After determining the data category of each data page, the managing device 301 designates one logical block for each data page according to the category of each data page, where the logical block A is designated for the hot data Page 0, the logical block C is designated for the warm data Page 1, and the logical block E is designated for the cold data Page 2. Optionally, the managing device 301 may further record, into each logical block designated for each to-be-written data page, a logical block address of each to-be-written data page corresponding to each logical block, that is, record a logical block address of the Page 0 into the logical block A, record a logical block address of the Page 1 into the logical block C, and record a logical block address of the Page 2 into the logical block E. After the managing device 301 designates one logical block for each data page, the managing device 301 sends the data write instruction to the SSD 302. The data write instruction includes the to-be-written data pages and information about the logical block of each to-be-written data page (the Page 0, the logical block A; the Page 1, the logical block C; and the Page 2, the logical block E).

After receiving the data write instruction, the SSD 302 determines, according to the information about the logical block of each to-be-written data page and the correspondence between physical blocks and logical blocks that is preset in the SSD 302, a physical block corresponding to each logical block, that is, the logical block A is corresponding to a physical block A and a physical block B; the logical block C is corresponding to a physical block C and a physical block D; and the logical block E is corresponding to a physical block E and a physical block F. Then, the SSD 302 stores the to-be-written data page Page 0 in the physical block A or the physical block B, stores the to-be-written data page Page 1 in the physical block C or the physical block D, and stores the to-be-written data page Page 2 in the physical block E or the physical block F.

By using this embodiment, a same physical block 303 of the SSD 302 may store only data pages of a same data category. In this way, if all data stored in a physical block 303 is hot data whose access frequency is relatively high, a possibility that all data in the physical block 303 is updated is relatively high. After hot data in a physical block that stores hot data is updated, the hot data stored in the physical block before updating becomes invalid data, that is, because a possibility that data in the physical block that stores hot data is updated is high, after data updating, there is a relatively large quantity of invalid pages in the physical block that stores hot data. Therefore, when the physical block is erased, a relatively small quantity of valid pages needs to be migrated, so that write amplification is effectively reduced.

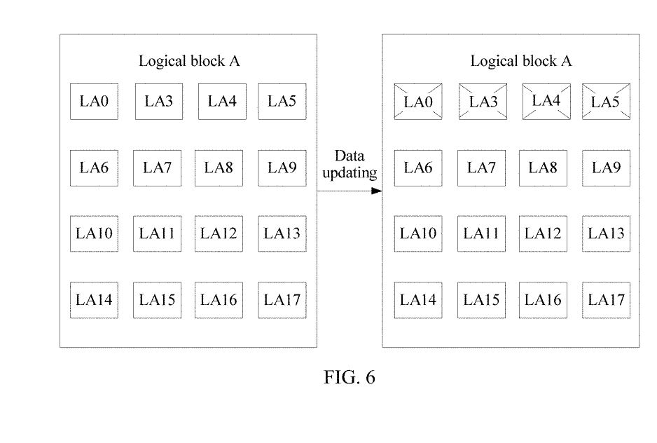

Further, in this embodiment, after designating a logical block for the to-be-written data page, the managing device 301 further records, into the logical block designated for the to-be-written data page, a logical block address of each to-be-written data page corresponding to each logical block, and when it is determined that a stored data page needs to be updated, invalidates a logical block address that is of the stored data page and that is recorded in a logical block corresponding to the stored data page. As shown in FIG. 6, if data pages Page 0, Page 3, Page 4, and Page 5 that are recorded in the logical block A are updated, logical block addresses LA 0, LA 3, LA 4, and LA 5 that are of the data pages Page 0, Page 3, Page 4, and Page 5 and that are recorded in the logical block A are invalidated. In this way, by recording a logical block address of each data page into a logical block, the managing device 301 can learn a category and a state of a data page stored inside the SSD, and can implement management of the data page stored in the SSD 302.

Further, in this embodiment, the managing device 301 may control erasure of the physical block 303 in the SSD 302. Specifically, the managing device 301 determines a to-be-erased logical block and sends an erase instruction to the SSD 302. The erase instruction carries information about the to-be-erased logical block.

The SSD 302 receives the erase instruction, determines a to-be-erased physical block 303 according to the information that is about the to-be-erased logical block and that is in the erase instruction and the correspondence between physical blocks 303 and logical blocks, and erases the to-be-erased physical block 303.

In this embodiment, the managing device 301 determines the to-be-erased logical block according to data pages corresponding to each logical block.

Further, the managing device 301 selects, as the to-be-erased logical block, a logical block whose data category is hot data or a logical block that has a large quantity of invalid logical block addresses.

Alternatively, the managing device 301 selects, as the to-be-erased logical block, a logical block whose data category is cold data.

Further, in this embodiment, before sending the erase instruction to the SSD 302, the managing device 301 further determines a to-be-migrated data page in the to-be-erased logical block according to a preset migration policy, and sends a data migration instruction to the SSD 302. The data migration instruction carries information about the to-be-migrated data page.

The SSD 302 migrates the to-be-migrated data page in the SSD 302 according to the data migration instruction.

The managing device 301 determines a data page in the to-be-erased logical block as the to-be-migrated data page, where a current data category of the data page is hot data, and a logical block address of the data page is valid.

The managing device 301 designates a logical block for the to-be-written data page according to a data category that is of the to-be-written data page at a time when data is written. However, the data category of the data page changes with the access characteristic; therefore, after the data page is recorded into the logical block, the data category of the data page recorded into the logical block changes because of a subsequent change of the access characteristic. For example, if a data category of a data page is hot data at a time when the data page is written, and the data page is never accessed after being designated to a logical block corresponding to hot data, the data page becomes cold data; or a data category of a data page is cold data at a time when the data page is written, and the data page becomes hot data after being designated to a logical block corresponding to cold data. Therefore, at a time when erasure is performed on the to-be-erased logical block, a data category of a data page recorded in the to-be-erased logical block may be different from a data category that is at a time when the data page is just recorded into the to-be-erased logical block. Therefore, when erasing is performed on the to-be-erased logical block, a category of the data page in the to-be-erased logical block may be further determined, so that only a data page of a specific category, for example, hot data or warm data, is migrated. In this way, a quantity of data migration may be further reduced, and write amplification is further reduced.

During data migration, the information that is about the to-be-migrated data page and that is carried in the data migration instruction is a logical block address of the to-be-migrated data page. After receiving the data migration instruction, the SSD 302 finds the to-be-migrated data page in the to-be-erased physical block according to the logical block address that is of the to-be-migrated data page and that is in the data migration instruction, and then migrates the to-be-migrated data page.

Further, after determining the to-be-migrated data page in the to-be-erased logical block, the managing device 301 further records the logical block address of the to-be-migrated data page into a logical block corresponding to the data category of the to-be-migrated data page. Correspondingly, the data migration instruction sent by the managing device 301 to the SSD 302 further carries information about the logical block corresponding to the data category of the to-be-migrated data page. The SSD 302 determines, according to the information that is about the logical block corresponding to the data category of the to-be-migrated data page and that is carried in the migration instruction, a physical block corresponding to the logical block corresponding to the data category of the to-be-migrated data page, and migrates the to-be-migrated data page to the physical block corresponding to the logical block corresponding to the data category of the to-be-migrated data page.

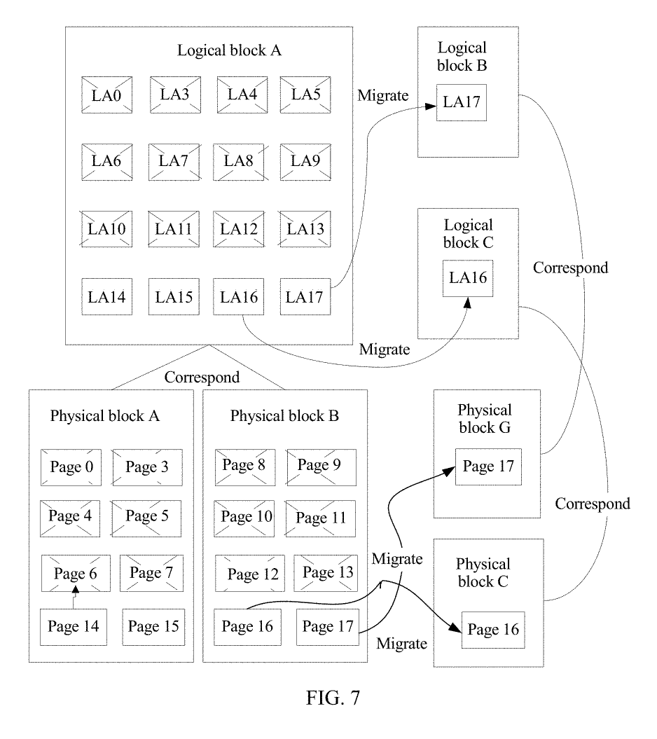

As shown in FIG. 7, the logical block A is selected as the to-be-erased logical block because of a relatively large quantity of invalid logical pages, but there are also valid logical block addresses LA 14, LA 15, LA 16, and LA 17 in the logical block A, where data categories corresponding to the valid logical block addresses LA 14 and LA 15 are cold data, and data categories corresponding to the LA 16 and the LA 17 are respectively warm data and hot data. In this case, it may be determined that to-be-migrated data pages are data pages corresponding to the valid logical block addresses LA 16 and LA 17. The valid logical block address LA 16 is migrated to the logical block C corresponding to warm data, and the valid logical block address LA 17 is migrated to the logical block B corresponding to hot data. Then, the managing device 301 sends a data migration instruction to the SSD 302, where the data migration instruction carries the logical block addresses LA 16 and LA 17 of the to-be-migrated data pages page 16 and page 17; and records information about logical blocks respectively corresponding to the LA 16 and the LA 17, that is, the logical block C and the logical block B.

After receiving the data migration instruction, the SSD 302 finds, according to the logical block addresses LA 16 and LA 17, the to-be-migrated data pages page 16 and page 17 in the to-be-erased physical block B corresponding to the to-be-erased logical block A; then migrates the to-be-migrated data page page 16 to a physical block C corresponding to the logical block in which the logical block address LA 16 is recorded, and migrates the to-be-migrated data page page 17 to a physical block G corresponding to the logical block in which the logical block address LA 17 is recorded. After data migration is completed, the SSD 302 may erase the to-be-erased physical block A and the to-be-erased physical block B.

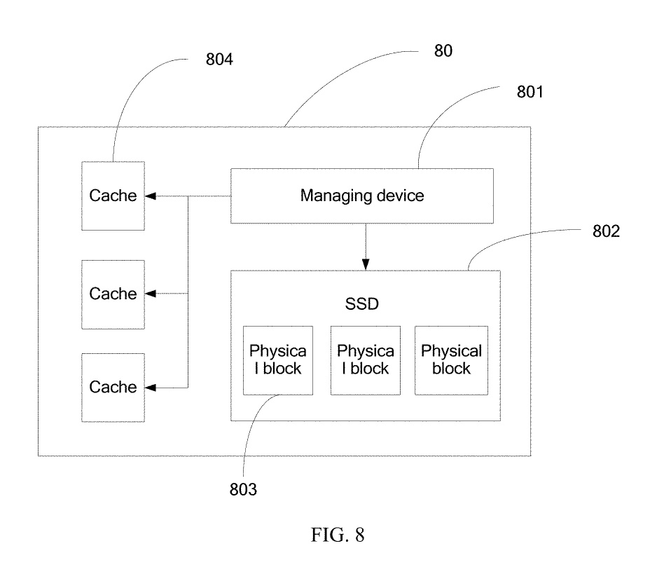

FIG. 8 is an architecture diagram of a second storage system 80 according to another embodiment of the present application. The second storage system 80 includes a managing device 801, an SSD 802, and at least one cache 804. The SSD 802 includes multiple physical blocks 803.

After receiving a data write request, the managing device 801 writes to-be-written data pages of different data categories to different caches 804, where to-be-written data pages written to each cache 804 are of a same data category; when any cache 804 is fully written, designates one logical block for data pages that are of a same category and that are in the fully written cache 804; and sends a data write instruction to the SSD 802. The data write instruction carries information about the logical block designated for the data pages in the fully written cache 804 and the data pages in the fully written cache 804. A capacity of each cache is less than or equal to a capacity of each logical block.

After receiving the data write instruction, according to the data write instruction, the SSD 802 allocates a physical block 803 to the logical block designated for the data pages in the fully written cache 804, and writes the data pages in the fully written cache 804 to the allocated physical block 803. The allocated physical block 803 is an idle physical block 803 in the SSD, and the idle physical block 803 is subsequently marked as non-idle. A total capacity of the allocated physical block 803 is greater than or equal to a capacity of the logical block designated for the data pages in the fully written cache 804.

In this embodiment, the idle physical block 803 may be marked as non-idle after the physical block 803 is allocated, or may be marked as non-idle after the data pages in the cache 804 are written to the physical block 803.

In the second storage system 80, a manner for classifying a data page category, a manner for establishing a correspondence between data categories and logical blocks, and a manner for designating a logical block for a to-be-written data page are the same as those in the first storage system 30, and details are not described herein.

In the second storage system 80, one cache is set for data pages of each data category. When the data write instruction is received, to-be-written data pages of a same data category are first written to a same cache, and then the data write instruction is sent to the SSD, to instruct the SSD to store, in a same physical block, data in the fully written cache. In this way, a same physical block 803 stores data of a same data category, and a data writing granularity can be increased, so that data writing efficiency is improved.

In the second storage system 80, erasure of data in a physical block 803, and a manner for migrating data in a to-be-erased physical block 803 before erasure are the same as those in the first storage system 30, and details are not described herein.

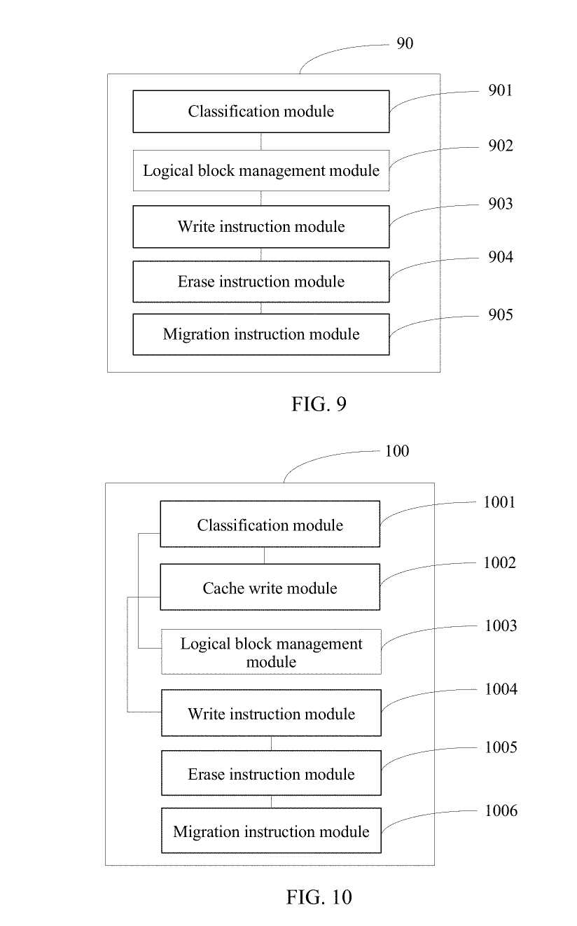

FIG. 9 is a block diagram of a first storage management apparatus 90 according to an embodiment of the present application. The first storage management apparatus 90 is applied to a storage system, the storage system includes an SSD, and the SSD includes multiple physical blocks. The first storage management apparatus 90 includes a classification module 901, a logical block management module 902, a write instruction module 903, an erase instruction module 904, and a migration instruction module 905.

The classification module 901 is configured to receive a data write request and determine a data category of a to-be-written data page.

A manner for classifying data by the classification module 901 is the same as the manner for classifying data by the managing device 301 in the first storage system 30, and details are not described herein.

The logical block management module 902 is configured to designate different logical blocks for to-be-written data pages of different data categories according to a classification result of the classification module 901. Each designated logical block is corresponding to to-be-written data pages of a same data category.

A manner for designating different logical blocks for to-be-written data pages of different data categories by the logical block management module 902 is the same as the manner for designating different logical blocks for to-be-written data pages of different data categories by the managing device 301 in the first storage system 30, and details are not described herein.

The write instruction module 903 is configured to send a data write instruction to the SSD according to the logical blocks designated by the logical block management module 902 for the to-be-written data pages. The data write instruction carries to-be-written data pages corresponding to at least one designated logical block, and the data write instruction is used to instruct the SSD to write, according to the data write instruction, the to-be-written data page corresponding to the at least one designated logical block to a physical block corresponding to the at least one designated logical block. To-be-written data pages corresponding to a same logical block are written to at least one physical block, and to-be-written data pages written to each physical block are corresponding to a same logical block.

The data write instruction further instructs the SSD to: query, according to information that is about the at least one designated logical block and that is in the data write instruction, a correspondence between physical blocks and logical blocks that is set in the SSD, determine the physical block corresponding to the at least one designated logical block, and write the to-be-written data page corresponding to the at least one designated logical block to the physical block corresponding to the at least one designated logical block.

After designating the different logical blocks for the to-be-written data pages of different data categories, the logical block management module 902 is further configured to record, into the at least one designated logical block, a logical block address of each to-be-written data page corresponding to the at least one designated logical block, and record a correspondence between the at least one designated logical block and a data category of a data page corresponding to the at least one designated logical block.

The erase instruction module 904 is configured to determine a to-be-erased logical block and send an erase instruction to the SSD. The erase instruction carries information about the to-be-erased logical block, and the erase instruction is used to instruct the SSD to determine a to-be-erased physical block according to the information that is about the to-be-erased logical block and that is in the erase instruction and the correspondence between physical blocks and logical blocks that is set in the SSD, and to erase the to-be-erased physical block.

Further, when it is determined that a stored data page needs to be updated, the logical block management module 902 invalidates a logical block address that is of the stored data page and that is recorded into a logical block corresponding to the stored data page.

The erase instruction module 904 determines the to-be-erased logical block according to data pages corresponding to each logical block.

Further, the erase instruction module 904 selects, as the to-be-erased logical block, a logical block whose data category is hot data or a logical block that has a large quantity of invalid logical block addresses.

Alternatively, the erase instruction module 904 selects, as the to-be-erased logical block, a logical block whose data category is cold data.

Before the erase instruction module 904 sends the erase instruction to the SSD, the migration instruction module 905 is configured to determine a to-be-migrated data page in the to-be-erased logical block according to a preset migration policy, and send a data migration instruction to the SSD. The data migration instruction carries information about the to-be-migrated data page, and the data migration instruction is used to instruct the SSD to migrate the to-be-migrated data page in the SSD.

The migration instruction module 905 determines a data page in the to-be-erased logical block as the to-be-migrated data page, where a current data category of the data page is hot data, and a logical block address of the data page is valid.

FIG. 10 is a block diagram of a second storage management apparatus 100 according to another embodiment of the present application. The second storage management apparatus 100 is applied to a storage system, the storage system includes an SSD and at least one cache, and the SSD includes multiple physical blocks. The storage management apparatus 100 includes a classification module 1001, a cache write module 1002, a logical block management module 1003, a write instruction module 1004, an erase instruction module 1005, and a migration instruction module 1006.

The classification module 1001 is configured to receive a data write request and determine a data category of a to-be-written data page.

The cache write module 1002 is configured to write to-be-written data pages of different data categories to different caches according to a classification result of the classification module 1001. To-be-written data pages of a same data category are written to a same cache, and a capacity of each cache is less than or equal to a capacity of each logical block. The logical block management module 1003 is configured to designate, according to the classification result of the classification module 1001, one logical block for data pages that are of a same data category and that are in each fully written cache.

When the cache is fully written by the cache write module 1002, the write instruction module 1004 is configured to send a data write instruction to the SSD according to a logical block designated by the logical block management module 1003 for the to-be-written data pages. The data write instruction carries information about at least one designated logical block and a data page corresponding to the at least one designated logical block.

The data write instruction is used to instruct the SSD to allocate a physical block to the at least one designated logical block, and to write the data page corresponding to the at least one designated logical block to the allocated physical block. The allocated physical block is an idle physical block in the SSD, and the idle physical block is marked as non-idle subsequently. A total capacity of the allocated physical block is greater than or equal to a capacity of the at least one designated logical block. In this embodiment, the idle physical block may be marked as non-idle after the physical block is allocated, or may be marked as non-idle after a data page in the cache are written to the physical block.

Functions executed by the erase instruction module 1005 and the migration instruction module 1006 are the same as functions executed by the erase instruction module 904 and the migration instruction module 905 that are in the first storage management apparatus 90, and details are not described herein.

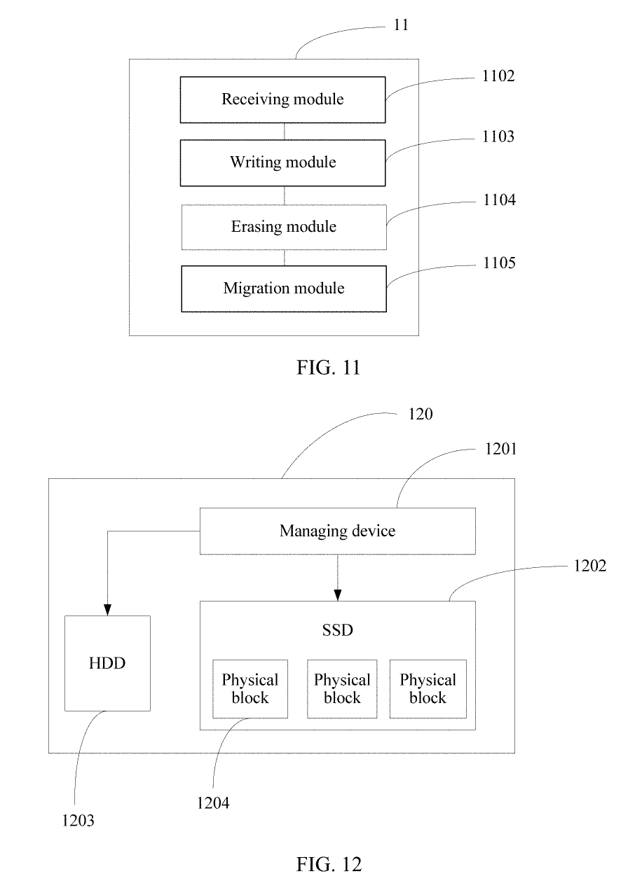

FIG. 11 is a block diagram of an SSD 11 according to an embodiment of the present application. The SSD 11 may be applied to a storage system, and the storage system includes a managing device. The SSD 11 includes a receiving module 1102, a writing module 1103, an erasing module 1104, and a migration module 1105.

The receiving module 1102 is configured to receive a data write instruction sent by the managing device. The data write instruction carries to-be-written data pages corresponding to at least one designated logical block and information about the at least one designated logical block. The data write instruction is sent by the managing device after the managing device determines a data category of the to-be-written data pages and designates different logical blocks for to-be-written data pages of different data categories. Each designated logical block is corresponding to to-be-written data pages of a same data category.

The writing module 1103 is configured to: query, according to the information that is about the at least one designated logical block and that is in the data write instruction, a correspondence between physical blocks and logical blocks that is set in the SSD 11, determine a physical block corresponding to the at least one designated logical block, and write the to-be-written data page corresponding to the at least one designated logical block to the physical block corresponding to the at least one designated logical block. Each physical block is corresponding to one logical block, and each logical block is corresponding to at least one physical block.

The receiving module 1102 is further configured to receive an erase instruction sent by the managing device. The erase instruction is sent by the managing device after the managing device determines a to-be-erased logical block, and the erase instruction carries information about the to-be-erased logical block.

The erasing module 1104 is configured to determine a to-be-erased physical block according to the information that is about the to-be-erased logical block and that is in the erase instruction and the correspondence between physical blocks and logical blocks, and erase the to-be-erased physical block.

The receiving module 1102 is further configured to receive a data migration instruction sent by the managing device. The data migration instruction is sent by the managing device after the managing device determines a to-be-migrated data page in the to-be-erased logical block according to a preset migration policy, and the data migration instruction carries information about the to-be-migrated data page.

The migration module 1105 is configured to migrate the to-be-migrated data page in the SSD according to the data migration instruction.

In a system that includes a cache and a managing device, the SSD 11 may be further configured to receive a data write instruction. The data write instruction is sent by the managing device after the managing device writes to-be-written data pages of different data categories to different caches, and when a cache is fully written, designates at least one logical block for data pages of a same data category in each fully written cache. To-be-written data pages written to each cache are of a same data category.

After the receiving module 1102 receives the data write instruction, according to the data write instruction, the writing module 1103 allocates a physical block to the at least one designated logical block and writes a data page corresponding to the at least one designated logical block to the allocated physical block. The allocated physical block is an idle physical block in the SSD 11, and the idle physical block is marked as non-idle subsequently. A total capacity of the allocated physical block is greater than or equal to a capacity of the at least one designated logical block.

The writing module 1103 is further configured to record the correspondence between physical blocks and logical blocks according to the information that is about the at least one designated logical block and that is in the data write instruction and information about the physical block allocated to the at least one designated logical block.

FIG. 12 is a structural diagram of a hybrid storage apparatus 120 according to an embodiment of the present application. The hybrid storage apparatus 12 includes a managing device 1201, an SSD 1202, and an HDD 1203. The SSD 1202 is used as a cache of the HDD, and the SSD 1202 includes multiple physical blocks 1204.

A function executed by the managing device 1201 is the same as the function executed by the managing device 301 in the first storage system 30 or the managing device 801 in the second storage system 80; a function executed by the SSD 1202 is the same as the function executed by the SSD 302 in the first storage system 30 or the SSD 802 in the second storage system 80. Details are not described herein.

An embodiment of the present application further provides a storage management method. The storage management method may be applied to a storage management system. The storage management system includes a managing device and an SSD, and the SSD includes multiple physical blocks. The storage management method includes two parts: A first part is a method for writing data to the SSD by the managing device, and a second part is a method for controlling, by the managing device, the SSD to perform data erasure.

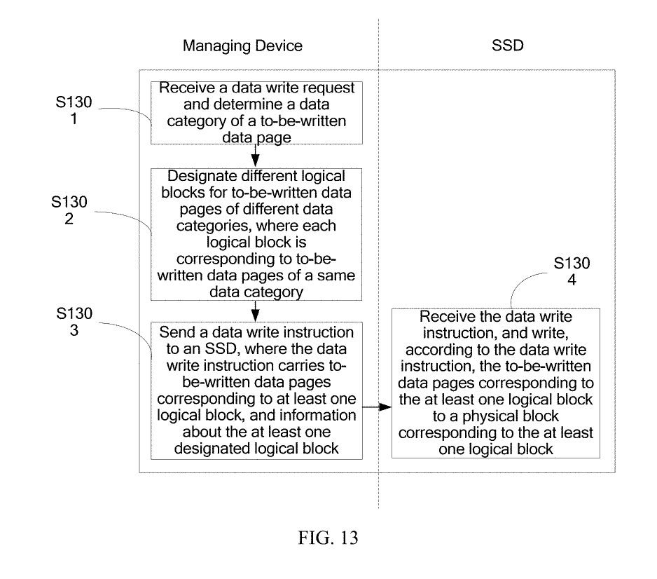

FIG. 13 is a flowchart of a method for writing data to the SSD by the managing device.

Step S1301: The managing device receives a data write request and determines a data category of a to-be-written data page.

Step S1302: The managing device designates different logical blocks for to-be-written data pages of different data categories, where each logical block is corresponding to to-be-written data pages of a same data category.

Step S1303: The managing device sends a data write instruction to the SSD, where the data write instruction carries to-be-written data pages corresponding to at least one logical block, and information about the at least one designated logical block.

Step S1304: The SSD receives the data write instruction, and writes, according to the data write instruction, the to-be-written data pages corresponding to the at least one logical block to a physical block corresponding to the at least one logical block, where to-be-written data pages corresponding to a same logical block are written to at least one physical block, and to-be-written data pages written to each physical block are corresponding to a same logical block.

After step S1302, the method may further include: the managing device records, into the at least one designated logical block, a logical block address of each to-be-written data page corresponding to the at least one designated logical block, and records a correspondence between the at least one designated logical block and a data category of a data page corresponding to the at least one designated logical block.

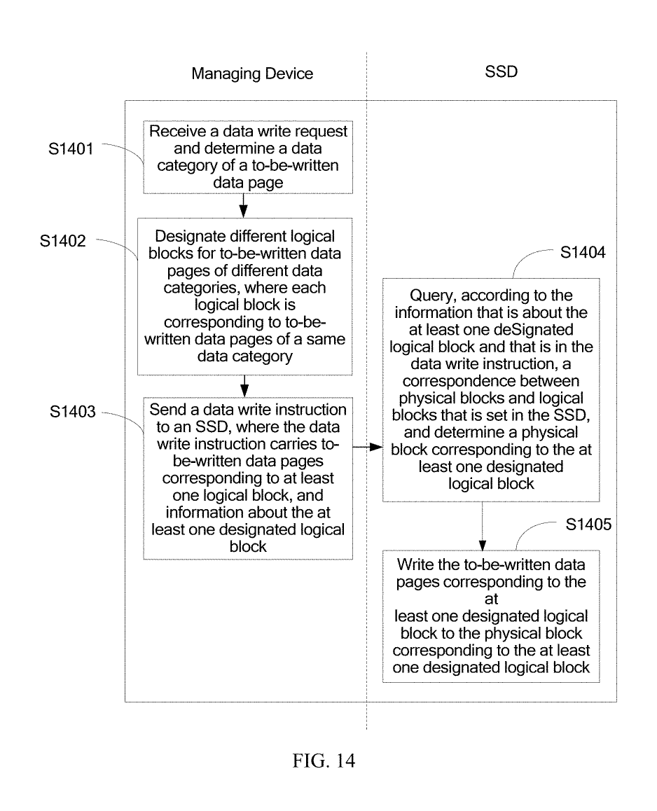

FIG. 14 is a flowchart of a first specific implementation method for writing data to the SSD by the managing device.

Step S1401: The managing device receives a data write request and determines a data category of a to-be-written data page.

Step S1402: The managing device designates different logical blocks for to-be-written data pages of different data categories, where each logical block is corresponding to to-be-written data pages of a same data category.

Step S1403: The managing device sends a data write instruction to the SSD, where the data write instruction carries to-be-written data pages corresponding to at least one logical block, and information about the at least one designated logical block.

Step S1404: The SSD queries, according to the information that is about the at least one designated logical block and that is in the data write instruction, a correspondence between physical blocks and logical blocks that is set in the SSD, and determines a physical block corresponding to the at least one designated logical block.

Step S1405: The SSD writes the to-be-written data page corresponding to the at least one designated logical block to the physical block corresponding to the at least one designated logical block.

After step S1402, the method may further include: the managing device records, into the at least one designated logical block, a logical block address of each to-be-written data page corresponding to the at least one designated logical block, and records a correspondence between the at least one designated logical block and a data category of a data page corresponding to the at least one designated logical block.

The storage management system to which the storage management method is applied further includes multiple caches. In the storage management system that includes the multiple caches, the managing device writes data to the SSD by using a second method.

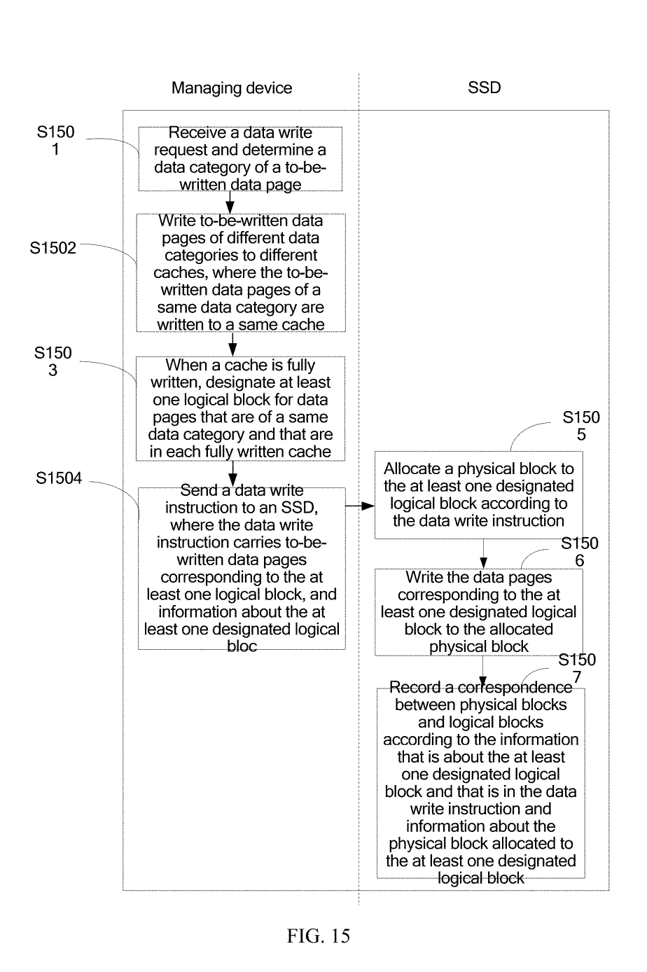

FIG. 15 is a flowchart of a second specific implementation method for writing data to the SSD by the managing device.

Step S1501: The managing device receives a data write request and determines a data category of a to-be-written data page.

Step S1502: The managing device writes to-be-written data pages of different data categories to different caches, where the to-be-written data pages of a same data category are written to a same cache.

Step S1503: When a cache is fully written, the managing device designates at least one logical block for data pages that are of a same data category and that are in each fully written cache.

Step S1504: The managing device sends a data write instruction to the SSD, where the data write instruction carries the to-be-written data pages corresponding to the at least one logical block, and information about the at least one designated logical block.

Step S1505: The SSD allocates a physical block to the at least one designated logical block according to the data write instruction.

Step S1506: The SSD writes a data page corresponding to the at least one designated logical block to the allocated physical block.

Step S1507: The SSD records a correspondence between physical blocks and logical blocks according to the information that is about the at least one designated logical block and that is in the data write instruction and information about the physical block allocated to the at least one designated logical block.

After step S1503, the method may further include: the managing device records, into the at least one designated logical block, a logical block address of each to-be-written data page corresponding to the at least one designated logical block, and records a correspondence between the at least one designated logical block and a data category of the data page corresponding to the at least one designated logical block.

The storage management method further includes: when it is determined that a stored data page needs to be updated, the managing device invalidates a logical block address that is of the stored data page and that is recorded into a logical block corresponding to the stored data page.

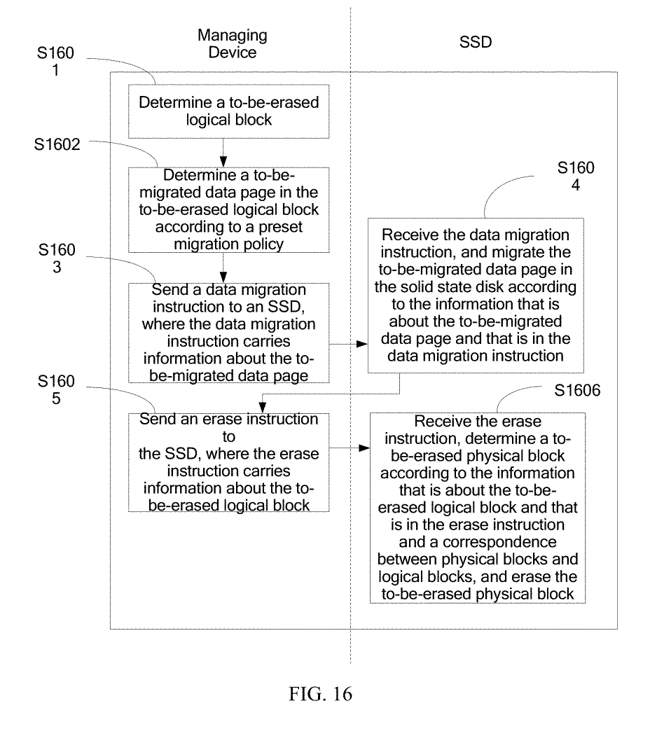

FIG. 16 is a flowchart of a method for controlling, by the managing device, the SSD to perform data erasure.

Step S1601: The managing device determines a to-be-erased logical block.

Step S1602: The managing device determines a to-be-migrated data page in the to-be-erased logical block according to a preset migration policy.

Step S1603: The managing device sends a data migration instruction to the SSD, where the data migration instruction carries information about the to-be-migrated data page.

Step S1604: The SSD receives the data migration instruction, and migrates the to-be-migrated data page in the SSD according to the information that is about the to-be-migrated data page and that is in the data migration instruction.

Step S1605: The managing device sends an erase instruction to the SSD, where the erase instruction carries information about the to-be-erased logical block.

Step 1606: The SSD receives the erase instruction, determines a to-be-erased physical block according to the information that is about the to-be-erased logical block and that is in the erase instruction and a correspondence between physical blocks and logical blocks, and erases the to-be-erased physical block.

The managing device may determine the to-be-erased logical block in two manners: Manner 1: determining the to-be-erased logical block according to a quantity of invalid logical block addresses in a designated logical block, where a quantity of invalid logical block addresses included in the to-be-erased logical block is greater than a preset value; and Manner 2: according to a correspondence between a designated logical block and a data category of data pages corresponding to the designated logical block, selecting, as the to-be-erased logical block, a logical block whose data category is cold data.

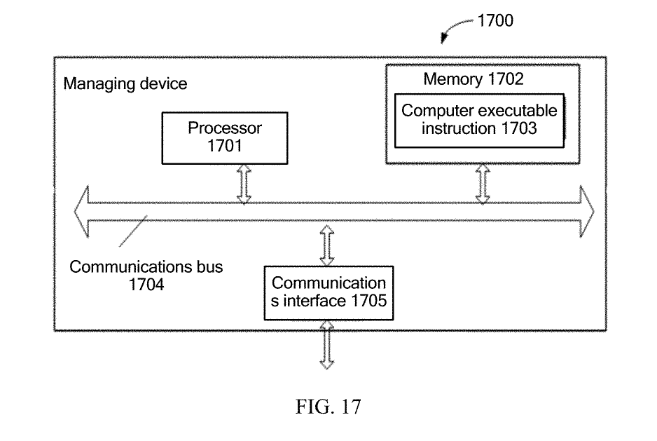

FIG. 17 is a schematic diagram of a structural composition of a storage managing device according to an embodiment of the present application. The storage managing device in this embodiment of the present application may include:

a processor 1701, a memory 1702, a system bus 1704, and a communications interface 1705. The processor 1701, the memory 1702, and the communications interface 1705 are connected by using the system bus 1704, and complete communication with each other.

The processor 1701 may be a single-core or multi-core central processing unit, or an application-specific integrated circuit, or one or more integrated circuits configured to implement this embodiment of the present application.

The memory 1702 may be a high-speed RAM memory, or may be a non-volatile memory, such as at least one magnetic disk storage.

The memory 1702 is configured to store a computer executable instruction 1703. Specifically, the computer executable instruction 1703 may include program code.

When the storage managing device runs, the processor 1701 may execute any one of the method procedures in FIG. 13 to FIG. 16 by executing the computer executable instruction 1703.

An embodiment of the present application further provides a computer readable medium, including a computer executable instruction. When a processor of a computer executes the computer executable instruction, the computer executes any one of the methods in FIG. 13 to FIG. 16.

In the present application, a function executed by an SSD improves an FTL of the SSD, and is executed by the FTL of the SSD, or may be an independent function module built into the SSD.

Persons of ordinary skill in the art may understand that all or a part of the steps of the methods in the foregoing embodiments may be implemented by a program instructing related hardware. The program may be stored in a computer readable storage medium. The storage medium may include: a ROM, a RAM, a magnetic disk, or an optical disc.

The storage system, the storage management apparatus, the storage device, the hybrid storage apparatus, and the storage management method provided in the embodiments of the present application are described in detail above. In this specification, specific examples are used to describe the principle and implementation manners of the present application. The descriptions of the foregoing embodiments are merely provided to help understand the method and core ideas of the present application. In addition, persons of ordinary skill in the art can make variations and modifications to the present application in terms of the specific implementation manners and application scopes according to the ideas of the present application. Therefore, the content of specification shall not be construed as a limitation to the present application.

What is claimed is:

1. A storage management method for use in a storage system that comprises a managing device and a storage device, wherein the storage device comprises a plurality of physical blocks, and the method comprising:
receiving, by the managing device, a data write request, wherein the data write request comprises one or more data pages to be written to the storage device;
determining, by the managing device, a data category for each data page comprised in the data write request;
allocating, by the managing device, each data page to a logical block, wherein data pages of different data categories are allocated to different logical blocks, and each logical block is allocated with data pages of a same category; and
sending, by the managing device, a data write instruction to the storage device;
wherein the data write instruction carries the data pages and information of the logical blocks the data pages are allocated to, and the data write instruction instructs the storage device to write the data pages to one or more physical blocks of the storage device that correspond to the logical blocks; and
wherein data pages allocated to a same logical block are written to one or more physical blocks that correspond to the logical block, and data pages written to each physical block are allocated to a same logical block.

2. The storage management method according to claim 1, further comprising:
querying, by the storage device according to the information about the logical blocks, a correspondence between physical blocks and logical blocks in the storage device to determine one or more physical blocks corresponding to each logical block; and
writing, by the storage device, the data pages to the physical blocks corresponding to the logical blocks.

3. The storage management method according to claim 2, wherein a physical block in the storage device for writing data pages to is an idle physical block, and the idle physical block is marked as non-idle physical block after being written with the data pages, and wherein a total capacity of the physical blocks corresponding to a logical block is greater than or equal to a capacity of the logical block.

4. The storage management method according to claim 1, wherein allocating each data page to a logical block comprises:
writing, by the managing device, data pages carried in the data write instruction into one or more caches, wherein data pages of different data categories are written into different caches, and data pages of a same data category are written into a same cache, and wherein a capacity of a cache is less than or equal to a capacity of a logical block; and
allocating, by the managing device, data pages written into each cache to one logical block.

5. The storage management method according to claim 1, further comprising:
after allocating each data page to a logical block, recording, by the managing device, a logical block address of the data page into the logical block.

6. The storage management method according to claim 1, wherein data categories of the data pages are cold data and hot data, and wherein determining a data category for each data page comprised in the data write request comprises:
determining a data category for each data page according to access frequency of the data page.

7. A storage management method for use in a storage system that comprises a managing device and a storage device, wherein the storage device comprises a plurality of physical blocks each storing one or more data pages, each data page is allocated to a logical block, data pages of different data categories are allocated to different logical blocks, and each logical block is allocated with data pages of a same category, wherein the method comprises:
selecting, by the managing device, a logical block according to a property of data pages allocated to the logical block; and
sending, by the managing device, an erase instruction to the storage device, wherein the erase instruction carries information about the selected logical block, and the erase instruction instructs the storage device to determine one or more physical blocks corresponding to the selected logical block, and to erase the physical blocks.

8. The storage management method according to claim 7, wherein the data categories are cold data and hot data, and a data category of a data page is determined according to access frequency of the data page, wherein when a data page stored in the storage device needs to be updated, a logical address of the data page, which is recorded in a logical block corresponding to the stored data page, is invalidated; wherein selecting the logical block comprises:
selecting a logical block that is allocated with data pages having the data category of hot data; or
selecting a logical block in which a quantity of invalid logical block addresses of data pages exceeds a preset limit.

9. The storage management method according to claim 7, wherein the data categories are cold data and hot data, and a data category of a data page is determined according to access frequency of the data page; and wherein selecting the logical block comprises:
selecting a logical block that is allocated with data pages having the data category of cold data;
and wherein the erase instruction further carries a garbage collection forbidden indication.

10. The storage management method according to claim 7, further comprising:
before sending the erase instruction to the storage device, identifying, by the managing device, one or more data page allocated to the selected logical block for migration according to a preset migration policy; and
sending, by the managing device, a data migration instruction to the storage device;
wherein the data migration instruction carries information about the identified data pages, and the data migration instruction instructs the storage device to migrate the identified data pages before erasing the physical blocks of the storage device.

11. The storage management method according to claim 10, wherein identifying the data pages for migration according to the preset migration policy comprises:
identifying a data page for migration if a current data category of the data page is hot data, and a logical block address of the data page is valid.

12. A method for use by a storage device, wherein the storage device comprises a plurality of physical blocks, the method comprising:
receiving, from a storage managing device, a data write instruction, wherein the data write instruction carries one or more data pages, the data pages are allocated to one or more logical blocks, data pages of different data categories are allocated to different logical blocks, and each logical block is allocated with data pages of a same data category; and
writing, according to the data write instruction, the data pages to one or more physical blocks corresponding to the one or more logical blocks, wherein data pages allocated to a same logical block are written to one or more physical blocks corresponding to the logical block, and data pages written to each physical block are allocated to a same logical block.

13. The method according to claim 12, wherein a preset correspondence between physical blocks and logical blocks is stored in the storage device, each physical block corresponds to one logical block, and each logical block corresponds to one or more physical blocks; wherein the data write instruction further carries information about the one or more logical blocks the data pages are allocated to; and wherein writing the data pages to one or more physical blocks comprises:
after receiving the data write instruction, querying, according to the information about the logical blocks, the correspondence between physical blocks and logical blocks to determine one or more physical blocks corresponding to each logical block; and
writing the data pages to the physical blocks corresponding to the logical blocks.

14. The method according to claim 12, wherein a physical block in the storage device for writing data pages to is an idle physical block, and the idle physical block is marked as non-idle physical block after being written with data pages, and wherein a total capacity of the physical blocks corresponding to each logical block is greater than or equal to a capacity of the logical block.

15. A method for use by a storage device, wherein the storage device comprises a plurality of physical blocks each storing one or more data pages, wherein each data page is allocated to a logical block, data pages of different data categories are allocated to different logical blocks, and each logical block is allocated with data pages of a same category, the method comprising:
receiving an erase instruction from a managing device, wherein the erase instruction carries information about a selected logical block, and the erase instruction instructs the storage device to erase one or more physical blocks corresponding to the selected logical block;
identifying the one or more physical blocks corresponding to the selected logical block according to a correspondence between physical blocks and logical blocks in the storage device; and
erasing the identified physical blocks.

16. The method according to claim 15, further comprising:
receiving a data migration instruction from the managing device, wherein the data migration instruction is sent by the managing device before sending the erase instruction and after determining, according to a preset migration policy, that one or more data pages allocated to the selected logical block need to be migrated, and the data migration instruction carries information about the to-be-migrated data pages; and
migrating the to-be-migrated data pages before erasing the identified physical blocks of the storage device.

17. The method according to claim 16, wherein the data categories are cold data and hot data, and a logical address of a data page is recorded in a logical block the data page is allocated to, and wherein a data pages is in need for migration if a current data category of the data page is hot data, and a logical block address of the data page is valid.

18. A storage managing device in a data storage system, comprising:
a processor, a network interface, and a non-transitory computer-readable storage medium coupled to the processor and storing programming instructions for execution by the processor,
wherein the programming instructions, when executed by the processor, cause the storage managing device to:
receive a data write request, wherein the data write request comprises one or more data pages to be written to a storage device of the storage system, and wherein the storage device comprises a plurality of physical blocks;
determine a data category for each data page comprised in the data write request;
allocate each data page to a logical block, wherein data pages of different data categories are allocated to different logical blocks, and each logical block is allocated with data pages of a same category; and
send a data write instruction to the storage device;
wherein the data write instruction carries the data pages and information of the logical blocks the data pages are allocated to, and the data write instruction instructs the storage device to write the data pages to one or more physical blocks of the storage device that correspond to the logical blocks, and
wherein data pages allocated to a same logical block are written to one or more physical blocks that correspond to the logical block, and data pages written to each physical block are allocated to a same logical block.

19. The storage managing device according to claim 16, wherein in allocating each data page to a logical block, the programming instructions cause the storage managing device to:
write data pages carried in the write instruction into one or more caches, wherein data pages of different data categories are written into different caches, and data pages of a same data category are written into a same cache, and wherein a capacity of a cache is less than or equal to a capacity of a logical block; and
allocate data pages written in each cache to one logical block.

20. The storage managing device according to claim 18, wherein the programming instructions further cause the storage managing device to:
after allocating each data page to a logical block, record a logical block address of the data page into the logical block.

21. The storage managing device according to claim 18, wherein data categories of the data pages are cold data and hot data, and wherein in determining a data category for each data page comprised in the data write request, the programming instructions cause the storage managing device to:
determine a data category for each data page according to access frequency of the data page.

22. The storage managing device according to claim 18, wherein the programming instructions further cause the storage managing device to:
select a logical block according to a property of data pages allocated to the logical block; and
send an erase instruction to the storage device,
wherein the erase instruction carries information about the selected logical block, and the erase instruction instructs the storage device to determine one or more physical blocks corresponding to the selected logical block, and to erase the physical blocks.

23. The storage managing device according to claim 22, wherein the data categories are cold data, and a data category of a data page is determined according to access frequency of the data page, wherein when a data page stored in the storage device needs to be updated, a logical address of the data page that is recorded in a logical block corresponding to the stored data page is invalidated; wherein in selecting the logical block, the programming instructions cause the storage managing device to:
select a logical block that is allocated with data pages having the data category of hot data; or
select a logical block in which a quantity of invalid logical block addresses of data pages exceeds a preset limit.

24. The storage managing device according to claim 22, wherein the data categories are cold data and hot data, and a data category of a data page is determined according to access frequency of the data page; and in selecting the logic block, the programming instructions cause the storage managing device to:
select a logical block that is allocated with data pages having the data category of cold data; and
wherein the erase instruction further carries a garbage collection forbidden indication.

25. The storage managing device according to claim 22, wherein the programming instructions further cause the storage managing device to:
before sending the erase instruction to the storage device, identify one or more data page allocated to the selected logical block for migration according to a preset migration policy; and
send a data migration instruction to the storage device,
wherein the data migration instruction carries information about the identified data pages, and the data migration instruction instructs the storage device to migrate the identified data pages before erasing the physical blocks of the storage device.

26. The storage managing device according to claim 25, wherein in identifying the data pages for migration according to the preset migration policy, the programming instructions cause the storage managing device to:
identify a data page for migration if a current data category of the data page is hot data, and a logical block address of the data page is valid.

27. A storage device in a data storage system, comprising:
a processor, a plurality of physical clocks, and a non-transitory computer-readable storage medium coupled to the processor and storing programming instructions for execution by the processor,
wherein the programming instructions, when executed by the processor, cause the storage device to:
receive, from a storage managing device, a data write instruction, wherein the data write instruction carries one or more data pages, the data pages are allocated to one or more logical blocks, data pages of different data categories are allocated to different logical blocks, and each logical block is allocated with data pages of a same data category; and
write, according to the data write instruction, the data pages to one or more physical blocks corresponding to the one or more logical blocks, wherein data pages allocated to a same logical block are written to one or more physical blocks corresponding to the logical block, and data pages written to each physical block are allocated to a same logical block.

28. The storage device according to claim 27, wherein a preset correspondence between physical blocks and logical blocks is stored in the storage device, wherein each physical block corresponds to one logical block, and each logical block corresponds to one or more physical blocks; wherein the data write instruction further carries information about the one or more logical blocks the data pages are allocated to; and wherein in writing the data pages to one or more physical blocks, the programming instructions cause the storage device to:
after receiving the data write instruction, query, according to the information about the logical blocks, the correspondence between physical blocks and logical blocks to determine one or more physical blocks corresponding to each logical block; and
write the data pages to the physical blocks corresponding to the logical blocks.

29. The storage device according to claim 27, wherein a physical block in the storage device for writing data pages to is an idle physical block, and the idle physical block is marked as non-idle physical block after being written with data pages, and wherein a total capacity of the physical blocks corresponding to each logical block is greater than or equal to a capacity of the logical block.

30. The storage device according to claim 27, wherein the programming instructions further cause the storage device to:
receive an erase instruction from the managing device, wherein the erase instruction carries information about a selected logical block, and the erase instruction instructs the storage device to erase one or more physical blocks corresponding to the selected logical block;
identify the one or more physical blocks corresponding to the selected logical block according to a correspondence between physical blocks and logical blocks in the storage device; and
erase the identified physical blocks.

31. The storage device according to claim 30, wherein the programming instructions further cause the storage device to:
receive a data migration instruction from the managing device, wherein the data migration instruction is sent by the managing device before sending the erase instruction and after determining, according to a preset migration policy, that one or more data pages allocated to the selected logical block need to be migrated, and the data migration instruction carries information about the to-be-migrated data pages; and
migrate the to-be-migrated data pages before erasing the identified physical blocks of the storage device.

32. The storage device according to claim 31, wherein the data categories are cold data and hot data, and a logical address of a data page is recorded in a logical block the data page is allocated to, and wherein a data pages is in need for migration if a current data category of the data page is hot data, and a logical block address of the data page is valid.

33. A computer program product, comprising a non-transitory computer-readable medium storing computer executable programming instructions, wherein when the programming instructions are executed by a processor of a storage managing device in a storage system, causes the storage managing device to:
receive a data write request, wherein the data write request comprises one or more data pages to be written to a storage device of the storage system, and wherein the storage device comprises a plurality of physical blocks;
determine a data category for each data page comprised in the data write request;
allocate each data page to a logical block, wherein data pages of different data categories are allocated to different logical blocks, and each logical block is allocated with data pages of a same category; and
send a data write instruction to the storage device,
wherein the data write instruction carries the data pages and information of the logical blocks the data pages are allocated to, and the data write instruction instructs the storage device to write the data pages to one or more physical blocks of the storage device that correspond to the logical blocks, and
wherein data pages allocated to a same logical block are written to one or more physical blocks that correspond to the logical block, and data pages written to each physical block are allocated to a same logical block.

34. A computer program product, comprising a non-transitory computer-readable medium storing computer executable programming instructions, wherein when the programming instructions are executed by a processor of a storage device in a storage system, causes the storage device to:
receive, from a storage managing device, a data write instruction, wherein the data write instruction carries one or more data pages, the data pages are allocated to one or more logical blocks, data pages of different data categories are allocated to different logical blocks, and each logical block is allocated with data pages of a same data category; and
write, according to the data write instruction, the data pages to one or more physical blocks of the storage device corresponding to the one or more logical blocks, wherein data pages allocated to a same logical block are written to one or more physical blocks corresponding to the logical block, and data pages written to each physical block are allocated to a same logical block.
